(19) United States
(12) Patent Application Publication
(10) Pub. No.: US 2014/0327462 A1
(43) Pub. Date: Nov. 6, 2014

(54) TEST SOCKET PROVIDING MECHANICAL STABILIZATION FOR POGO PIN CONNECTIONS

(71) Applicant: Avago Technologies General IP (Singapore) Pte. Ltd., (US)

(72) Inventors: Jin JEONG, Kyunggi province (KR); Chris CHUNG, Seoul (KR); Kyung Man HA, Gyeonggi-do (KR)

(73) Assignee: Avago Technologies General IP (Singapore) Pte. Ltd., Singapore (SG)

(21) Appl. No.: 13/886,434

(22) Filed: May 3, 2013

(51) Int. Cl. G01R 1/04

(52) U.S. Cl. CPC G01R 1/0416
USPC 324/756.02

(57) ABSTRACT

A test socket for electrically connecting a device under test (DUT) to an electrical signal source comprises a plurality of pogo pins spaced apart from each other, a stabilizing plate supporting the plurality of pogo pins, a plurality of conductive lines passing through the stabilizing plate and configured to electrically connect the electrical signal source to the pogo pins, and at least one inner stabilizer disposed in the stabilizing plate between the conductive lines and configured to apply an elastic force toward the DUT where the DUT is brought into contact with the pogo pins.

### BACKGROUND

Electrical devices are generally tested for manufacturing defects before they are put into commercial circulation. Such testing may be performed by connecting the devices to a test instrument using a test socket having probes such as pogo pins.

FIG. 1 illustrates a conventional test socket comprising pogo pins to be connected to a device under test (DUT), and FIGS. 2A and 2B show examples of contact failures between contact terminals of the DUT and the pogo pins in the conventional test socket.

Referring to FIG. 1, a DUT 20 comprises contact terminals 22 formed on one of its surfaces to receive an electrical signal through pogo pins 12. A test socket 10 comprises pogo pins 12 connected to an electrical signal source via an RF cable 14. Where DUT 20 is brought into contact with pogo pins 12, an electrical signal is transmitted from RF cable 14 to DUT 20 through pogo pins 12. The application of the electrical signal to DUT 20 allows DUT 20 to be tested.

In general, a handler having a driving unit such as stepping motor is utilized to move DUT 20 toward pogo pins 12. DUT 20, however, may be susceptible to mechanical disturbances such as vibrations or shock caused by the driving unit. The mechanical disturbances may cause a contact failure between pogo pins 12 and DUT 20 where DUT 20 is brought into contact with pogo pins 12. For example, DUT 20 may be tilted from a desired position 30 as illustrated in FIG. 2A, or deviated from the desired position 30 as illustrated in FIG. 2B. Such a contact failure may produce erroneous test results of DUT 20. For instance, DUT 20 may be erroneously determined to be defective due to the contact failure, thereby undermining the reliability of test results of DUT 20.

In view of the above and other shortcomings of conventional test sockets, there is a general need for test sockets having a reduced likelihood of contact failures between pogo pins and a DUT.

### SUMMARY

In a representative embodiment, a test socket for electrically connecting a DUT to an electrical signal source comprises a plurality of pogo pins spaced apart from each other, a stabilizing plate supporting the plurality of pogo pins, a plurality of conductive lines passing through the stabilizing plate and configured to electrically connect the electrical signal source to the pogo pins, and at least one inner stabilizer disposed in the stabilizing plate between the conductive lines and configured to apply an elastic force toward the DUT where the DUT is brought into contact with the pogo pins. In certain embodiments, the test socket further comprises a guide disposed on the stabilizing plate around the pogo pins and configured to guide the DUT toward the pogo pins. The guide is typically a metal guide having a height greater than or equal to a sum of a height of the DUT and a height of the pogo pins. In certain embodiments, the electrical signal source is configured to transmit an RF signal to the DUT through the conductive lines and the pogo pins.

In certain embodiments, the test socket further comprises an outer stabilizer disposed in the stabilizing plate outside the conductive lines. A width of the outer stabilizer is typically greater than or equal to a width of the inner stabilizer.

In certain embodiments, the test socket further comprises an additional stabilizing plate disposed below the stabilizing plate, wherein the plurality of conductive lines pass through the additional stabilizing plate, and an internal stabilizer disposed in the additional stabilizing plate between the conductive lines and configured to apply an elastic force toward the DUT where the DUT is brought into contact with the pogo pins. An external stabilizer may be disposed in the additional stabilizing plate outside the conductive lines.

In certain embodiments, the test socket further comprises a socket housing comprising a radio frequency (RF) port for transmitting an electrical signal from the electrical signal source to the pogo pins, a base substrate disposed between the stabilizing plate and the RF port, and a plurality of RF cables disposed in the base substrate and configured to connect the RF port to the conductive lines of the stabilizing plate. The socket housing may further comprise a wall disposed on the base substrate to cover outer surfaces of the stabilizing plate and a guide formed around the pogo pins.

In another representative embodiment, a test system comprises a test instrument configured to generate test signals to be applied to a DUT, and a test socket configured to connect the test instrument to the DUT, and comprising a plurality of pogo pins spaced apart from each other, a stabilizing plate supporting the plurality of pogo pins, a plurality of conductive lines passing through the stabilizing plate and configured to electrically connect the test instrument to the pogo pins, and at least one inner stabilizer disposed in the stabilizing plate between the conductive lines and configured to apply an elastic force toward the DUT where the DUT is brought into contact with the pogo pins.

### BRIEF DESCRIPTION OF THE DRAWINGS

The present teachings are best understood from the following detailed description when read with the accompanying drawing figures. The features are not necessarily drawn to scale. Wherever practical, like reference numerals refer to like features.

FIG. 1 illustrates conventional test socket configured to connect a test instrument to a DUT.

FIG. 2A shows an example of a contact failure between contact terminals of the DUT and the pogo pins in the conventional test socket.

FIG. 2B shows another example of a contact failure between contact terminals of the DUT and the pogo pins in the conventional test socket.

FIG. 3 illustrates a test socket in accordance with a representative embodiment.

FIG. 4 illustrates a test socket in accordance with another representative embodiment.

FIG. 5 illustrates a system for testing a stabilizing plate of a test socket in accordance with a representative embodiment.

FIG. 6 is a diagram illustrating force magnitude curves for the system illustrated in FIG. 5.

FIG. 7 illustrates a system for testing a test socket in accordance with a representative embodiment.

FIG. 8 is a diagram illustrating isolation values computed by the system of FIG. 7.

FIG. 9 is a diagram illustrating yield rate curves for the respective test sockets of FIGS. 3 and. 4.

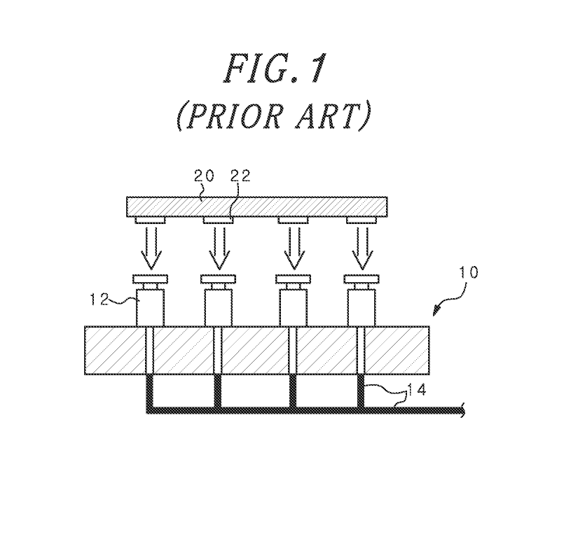

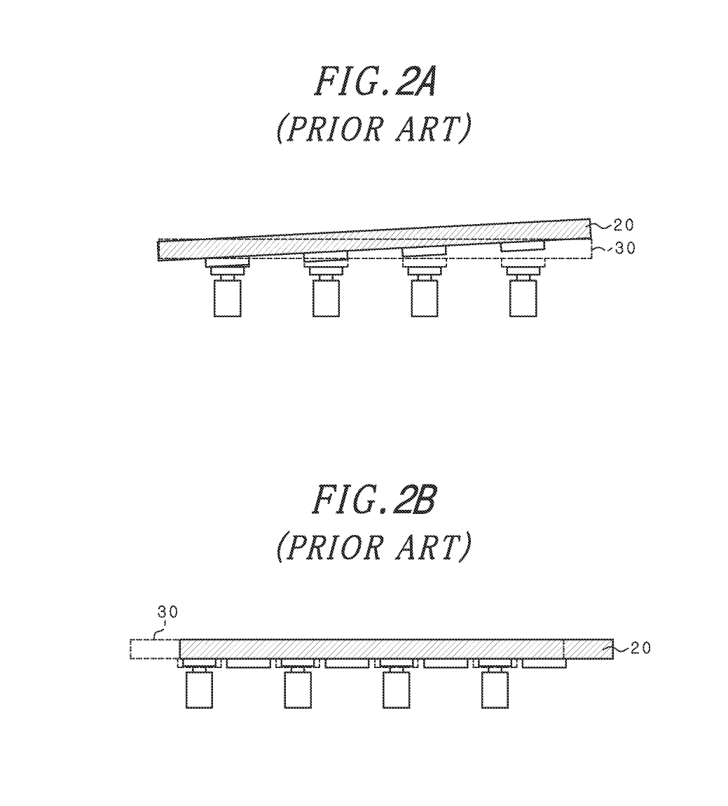

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms ‘a’, ‘an’ and ‘the’ include both singular and plural referents, unless the context clearly dictates otherwise. Thus, for example, ‘a device’ includes one device and plural devices. The terms ‘substantial’ or ‘substantially’ mean to within acceptable limits or degree. The term ‘approximately’ means to within an acceptable limit or amount to one of ordinary skill in the art. Relative terms, such as “above,” “on”, “below,” “under”, etc., may be used to describe the various elements' relationships to one another, as illustrated in the accompanying drawings. These relative terms are intended to encompass different orientations of the device and/or elements in addition to the orientation depicted in the drawings. For example, if a device were inverted with respect to the view in the drawings, an element described as “above” another element, for example, would now be below that element. Other relative terms may also be used to indicate the relative location of certain features along a path such as a signal path. For instance, a second feature may be deemed to “follow” a first feature along a signal path if a signal transmitted along the path reaches the second feature before the second feature.

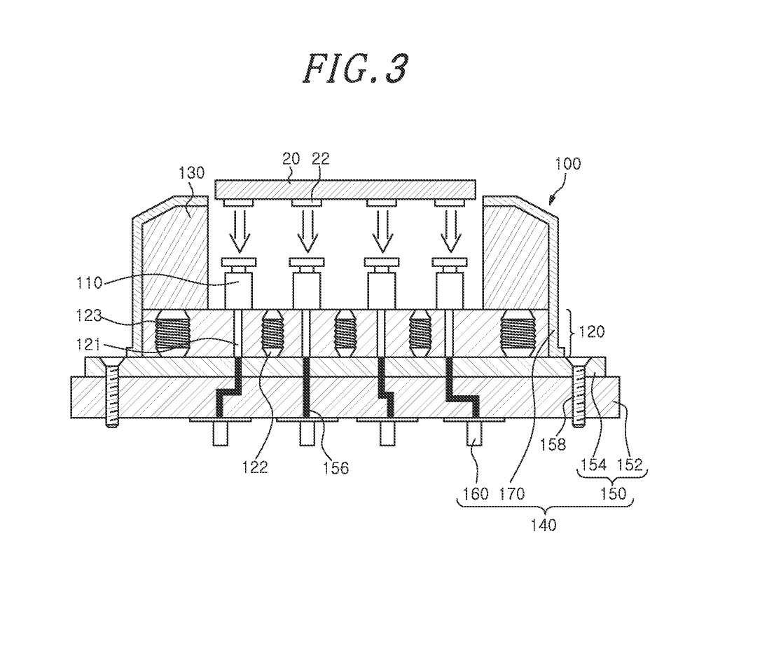

FIG. 3 illustrates a test socket 100 in accordance with a representative embodiment. Test socket 100 electrically connects a DUT to an electrical signal source (not shown). In general, an electrical signal source can be any type of apparatus configured to provide test signals to a DUT via test socket 100. For instance, it may comprise an arbitrary waveform generator, a power supply, or a frequency synthesizer, to name but a few.

Referring to FIG. 3, test socket 100 comprises a plurality of pogo pins 110, a stabilizing plate 120, a metal guide 130, and a socket housing 140. Socket housing 140 comprises abase substrate 150, an RF port 160, and a wall 170. Base substrate 150 comprises a printed circuit board (PCB) 152 and a contact body 154.

Pogo pins 110 each have substantially the same height and are disposed on a top surface of stabilizing plate 120. Additionally, pogo pins 110 are spaced apart from each other as a plurality of contact terminals 22 are spaced apart from each other. Where DUT 20 is brought into contact with pogo pins 110, pogo pins 110 touch contact terminals 22.

Stabilizing plate 120 comprises a plurality of conductive lines 121 and an inner stabilizer 122 disposed between conductive lines 121. The electrical signal source is electrically connected to pogo pins 110 through conductive lines 121. Inner stabilizer 122 applies an elastic force toward DUT 20, i.e. upward where DUT 20 is brought down into contact with pogo pins 110. That is to say, inner stabilizer 122 is configured to absorb an impact that occurs where DUT 20 is pressed downward. Thus, although DUT 20 is tilted at a specific slope where DUT 20 moves downward to pogo pins 110. DUT 20 may become parallel as stabilizing plate 120 applies the elastic force to DUT 20 to thereby suppress a contact failure between DUT 20 and pogo pins 110.

In some embodiments, stabilizing plate 120 comprises an outer stabilizer 123 disposed outside conductive lines 121. A width of outer stabilizer 123 is typically greater than or equal to a width of inner stabilizer 122.

Inner and outer stabilizer 122 and 123 may be made of an elastic material. For instance, inner and outer stabilizer 122 and 123 is made of silicon (Si), or inner and outer stabilizer 122 and 123 is an air stabilizer. Furthermore, a spiral groove may be formed along an outer surface of inner and outer stabilizer 122 and 123. Owing to the spiral groove, inner and outer stabilizer 122 and 123 may absorb external impacts and apply the elastic force outwardly.

Metal guide 130 is disposed on stabilizing plate 120 and surrounds pogo pins 110. Metal guide 130 guides DUT 20 to an inside of metal guide 130 where DUT 20 is brought in contact with pogo pins 110. In some embodiments, a height of metal guide 130 is greater than or equal to a sum of a height of DUT 20 and a height of pogo pins 110 to guide DUT 20 more effectively. In some embodiments, the metal guide is made of copper (Cu).

Base substrate 150 is disposed between stabilizing plate 120 and RF port 160. PCB 152 of base substrate 150 comprises a plurality of cables 156 for electrically connecting RF port 160 to conductive lines 121 of stabilizing plate 120. Contact body 154 of base substrate 150 is disposed on a top surface of PCB 152, and it is fastened to PCB 152 by at least one fastening element 158. Furthermore, contact body 154 acts as a connection medium between stabilizing plate 120 and PCB 152.

RF port 160 is disposed below PCB 152 and is configured to transmit an electrical signal from the electrical signal source to pogo pins 110.

Wall 170 is disposed on base substrate 150, and it covers outer surfaces of stabilizing plate 120 and metal guide 130. In some embodiments, wall 170 is made of gold (Au).

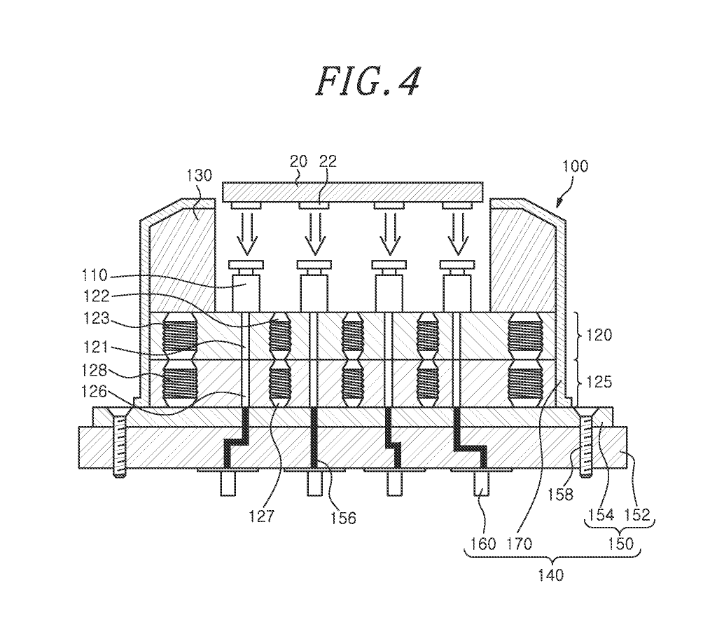

FIG. 4 illustrates test socket 100 in accordance with another representative embodiment. This embodiment is similar to that illustrated in FIG. 3, except that an additional stabilizing plate 125 is disposed below stabilizing plate 120. Here, additional stabilizing plate 125 comprises a plurality of conductive lines 126. Through conductive lines 126, the electrical signal source is electrically connected to conductive lines 121 of stabilizing plate 120. Additional stabilizing plate 125 further comprises an internal stabilizer 127 disposed between conductive lines 126 of additional stabilizing plate 125. Internal stabilizer 127 applies an elastic force toward DUT 20, i.e., upward when DUT 20 is brought into contact with pogo pins 110. In some embodiments, additional stabilizing plate 125 comprises an external stabilizer 128 disposed outside conductive lines 126. For example, a width of external stabilizer 128 is equal to or greater than a width of internal stabilizer 127.

In various alternative embodiments, stabilizing plate 120 and additional stabilizing plate 125 have the same or different heights. In general, the height of each of stabilizing plate 120 and additional stabilizing plate 125 may be determined based on yield rates of DUT 20.

Stabilizing plate 120 and additional stabilizing plate 125 are typically formed by laying conductive lines 121 on top of conductive lines 126 and inner and outer stabilizer 122 and 123 on top of internal and external stabilizer 127 and 128 in a vertical direction, respectively. Furthermore, pogo pins 110 may be disposed on the top surface of conductive lines 121.

Test socket 100 may be used for a test instrument to test a large number of PCBs with improved test results. It may potentially reduce the number of situations where a PCB that is not actually defective is classified as a defective product in a test due to a contact failure. Further, test socket 100 may change the relative orientation of DUT 20 from tilted to parallel by employing stabilizers 122, 123, 127 and 128 in stabilizing plates 120 and 125. Furthermore, test socket 100 can potentially reduce contact failure between contact terminals 22 of the DUT and pogo pins 110 by employing metal guide 130.

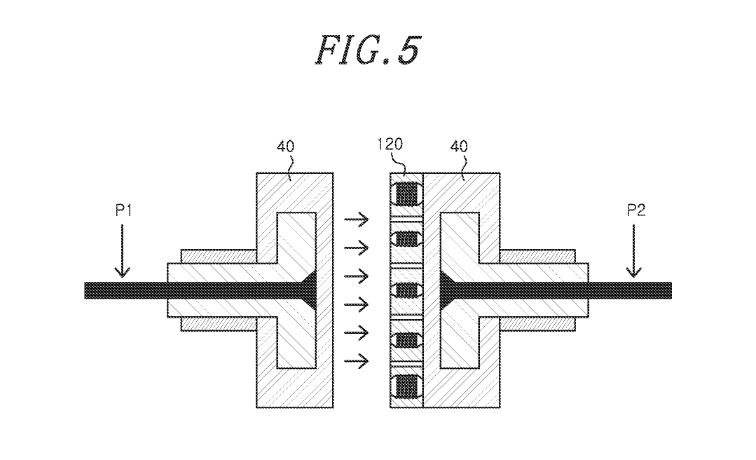

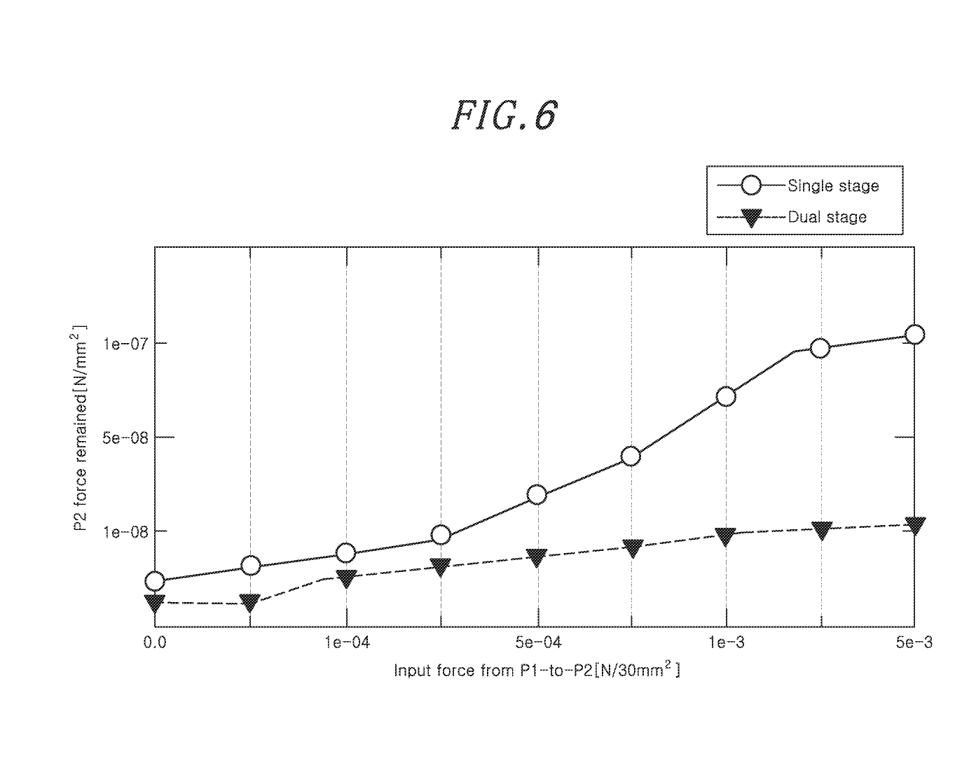

FIG. 5 illustrates a system for testing a stabilizing plate of test socket 100 in accordance with a representative embodiment, and FIG. 6 a diagram illustrating force magnitude curves computed in the system of FIG. 5.

Referring to FIG. 5, the system comprises a stabilizing plate 120 and sensors 40 attached to respective right and left sides of stabilizing plate 120. Here, a handler is provided to exert force onto the prototype of stabilizing plate 120. The exertion of force by the handler produces different amounts of force at different reference points P1 and P2 shown in FIG. 5. The respective magnitudes of those forces are illustrated in FIG. 6.

Referring to FIG. 6, force exerted at a reference point P1 is measured first, and then force transferred by the prototype is measured at a measurement point P2. The magnitude of force exerted at measurement point P2 is illustrated. A case where a dual stage comprising stabilizing plate 120 and additional stabilizing plate 125 is used may be compared with a case where a single stage only comprising stabilizing plate 120 is used. As the amount of force exerted from reference point P1 to measurement point P2 increases, the force transferred to measurement point P2 increases in both the case of the single stage and the case of the dual stage. It can be seen, however, that the force received at measurement point P2 in the case of the dual stage is relatively lower than that received at measurement point P2 in the case of the single stage. Because the extent of transmission of exerted force tends to decrease as the number of stabilizing plates increases, it may be beneficial to appropriately adjust the number of stabilizing plates based on the extent of force that is exerted when the DUT is lowered downward.

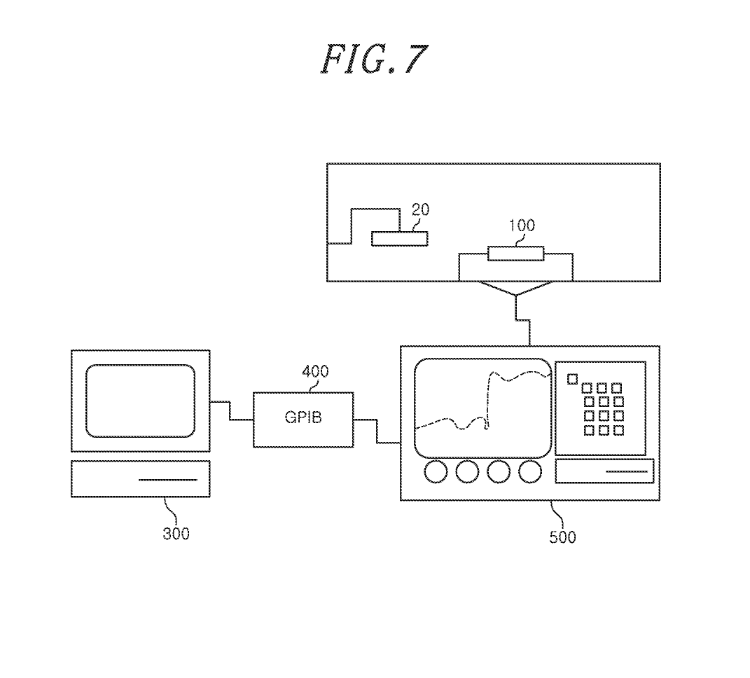

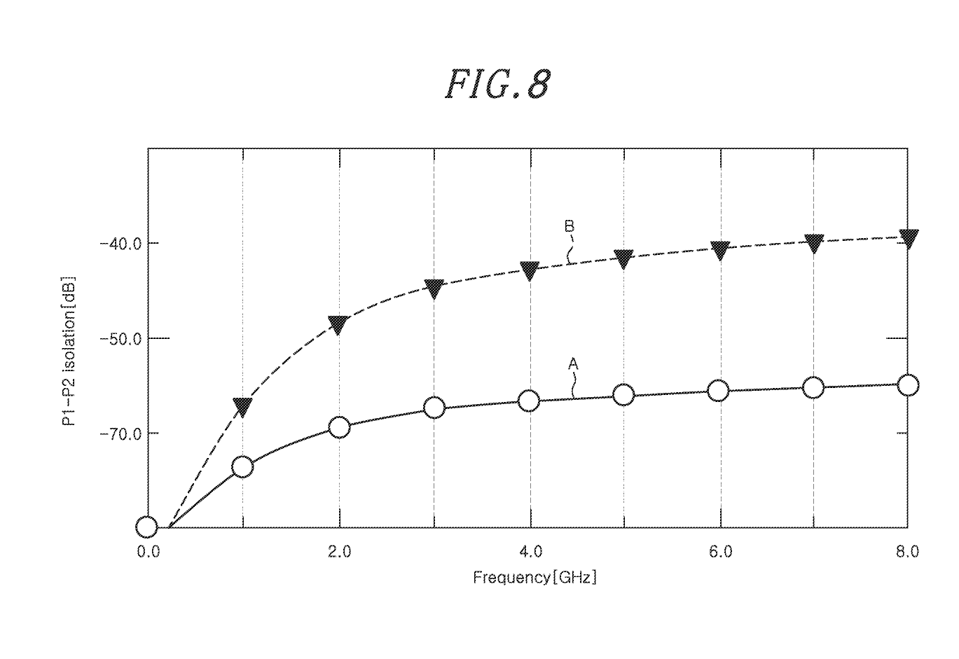

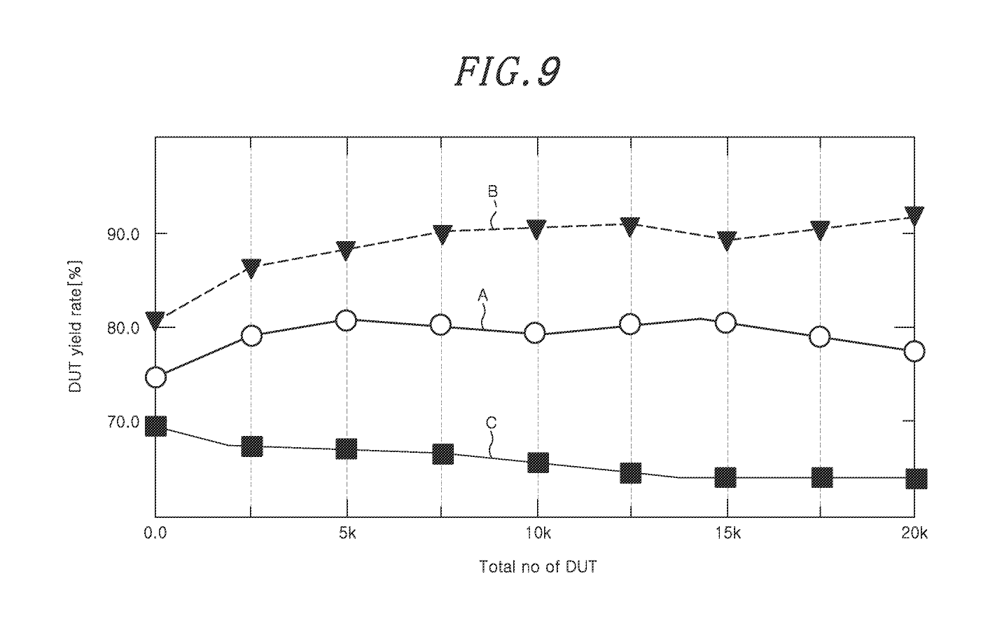

FIG. 7 illustrates a system for testing the test socket in accordance with a representative embodiment, FIG. 8 is a diagram depicting isolation values computed by the system of FIG. 7, and FIG. 9 is a diagram comparing yield rate curves for the respective test sockets of FIGS. 3 and 4.

Referring to FIG. 7, the system tests whether contact terminals 22 have been appropriately connected to pogo pins 110 while DUT 20 is pressed toward test socket 100 under control of a handler. The system comprises a host Personal Computer (PC) 300, a General Purposed Interface Bus (GPIB) 400 and a high-precision network analyzer 500. Network analyzer 500 may be a high-precision vector network analyzer, and is provided to measure isolation.

Referring to FIG. 8, as frequency increases, a isolation between reference point P1 and measurement point P2 increases. In FIG. 8, a curve A shows data for test socket 100 of FIG. 3, and a curve B shows data for a conventional test socket.

Because the unit of the isolation value is −dB, the lower the value, the better the isolation performance. Curve A for a test socket 100 indicates higher isolation performance than curve B for the conventional test socket.

Referring to FIG. 9, the DUT yield rate based on the total number of DUTs is illustrated. Here, a curve A represents a yield rate for a test socket to which the single stage only including stabilizing plate 120 has been applied, and a curve B represents a yield rate for a test socket to which a dual stage including stabilizing plate 120 and additional stabilizing plate 125 has been applied, and a curve C represents a yield rate for a conventional test socket.

As illustrated by FIG. 9, as the number of DUTs increases, curve C of the yield rate for the conventional test socket gradually decreases. Meanwhile, yield rates for curve A and curve B are kept higher than that for curve C. Furthermore, the yield rate for curve A is higher than curve B.

As indicated by the foregoing, a test socket in accordance with various representative embodiments may be used for an apparatus for testing a large number of PCBs, acquiring relatively accurate test results, and reducing a problem where a PCB that is actually not defective is determined to be defective during a test due to a contact failure. Such test sockets may be capable of changing the relative orientation of a DUT from tilted to parallel to pogo pins or the ground by employing stabilizers in stabilizing plates. Furthermore, such test sockets may be capable of reducing contact failures between the contact terminals of the DUT and the pogo pins using the metal guide.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

What is claimed is:

1. A test socket for electrically connecting a device under test (DUT) to an electrical signal source, comprising:
a plurality of pogo pins spaced apart from each other;
a stabilizing plate supporting the plurality of pogo pins;
a plurality of conductive lines passing through the stabilizing plate and configured to electrically connect the electrical signal source to the pogo pins; and
at least one inner stabilizer disposed in the stabilizing plate between the conductive lines and configured to apply an elastic force toward the DUT where the DUT is brought into contact with the pogo pins.

2. The test socket of claim 1, further comprising a guide disposed on the stabilizing plate around the pogo pins and configured to guide the DUT toward the pogo pins.

3. The test socket of claim 1, wherein the guide is a metal guide.

4. The test socket of claim 1, further comprising an outer stabilizer disposed in the stabilizing plate outside the conductive lines.

5. The test socket of claim 4, wherein a width of the outer stabilizer is greater than or equal to a width of the inner stabilizer.

6. The test socket of claim 1, further comprising:
an additional stabilizing plate disposed below the stabilizing plate, wherein the plurality of conductive lines pass through the additional stabilizing plate; and
an internal stabilizer disposed in the additional stabilizing plate between the conductive lines and configured to apply an elastic force toward the DUT where the DUT is brought into contact with the pogo pins.

7. The test socket of claim 6, further comprising an external stabilizer disposed in the additional stabilizing plate outside the conductive lines.

8. The test socket of claim 2, wherein the guide has a height greater than or equal to a sum of a height of the DUT and a height of the pogo pins.

9. The test socket of claim 1, further comprising a socket housing comprising:
a radio frequency (RF) port for transmitting an electrical signal from the electrical signal source to the pogo pins;
a base substrate disposed between the stabilizing plate and the RF port; and
a plurality of RF cables disposed in the base substrate and configured to connect the RF port to the conductive lines of the stabilizing plate.

10. The test socket of claim 9, wherein the socket housing further comprises a wall disposed on the base substrate to cover outer surfaces of the stabilizing plate and a guide formed around the pogo pins.

11. The test socket of claim 10, wherein the wall comprises gold (Au).

12. The test socket of claim 1, wherein the inner stabilizer comprises an elastic material.

13. The test socket of claim 12, wherein the inner stabilizer comprises silicon (Si).

14. The test socket of claim 12, wherein the inner stabilizer is an air stabilizer.

15. The test socket of claim 1, wherein the metal guide comprises copper (Cu).

16. The test socket of claim 1, wherein the inner stabilizer comprises a spiral groove along an outer surface thereof.

17. The test socket of claim 7, wherein the outer stabilizer comprises a spiral groove along an outer surface thereof.

18. The test socket of claim 1, wherein the electrical signal source is configured to transmit a radio frequency (RF) signal to the DUT through the conductive lines and the pogo pins.

19. A test system, comprising:
a test instrument configured to generate test signals to be applied, to a device under test (DUT); and
a test socket configured to connect the test instrument to the DUT, and comprising a plurality of pogo pins spaced apart from each other, a stabilizing plate supporting the plurality of pogo pins, a plurality of conductive lines passing through the stabilizing plate and configured to electrically connect the test instrument to the pogo pins, and at least one inner stabilizer disposed in the stabilizing plate between the conductive lines and configured to apply an elastic force toward the DUT where the DUT is brought into contact with the pogo pins.

20. The test system of claim 19, wherein the test socket further comprises an additional stabilizing plate disposed below the stabilizing plate, wherein the plurality of conductive lines pass through the additional stabilizing plate, and an internal stabilizer disposed in the additional stabilizing plate between the conductive lines and configured to apply an elastic force toward, the DUT where the DUT is brought into contact with the pogo pins.
